(19) United States
(12) Patent Application Publication
(10) Pub. No.: US 2025/0330128 A1
(43) Pub. Date: Oct. 23, 2025

(54) AMPLIFIER

(71) Applicant: Mitsubishi Electric Corporation, Tokyo (JP)

(72) Inventors: Keigo NAKATANI, Tokyo (JP); Yoshifumi KAWAMURA, Tokyo (JP)

(73) Assignee: Mitsubishi Electric Corporation, Tokyo (JP)

(21) Appl. No.: 19/256,533

(22) Filed: Jul. 1, 2025

Related U.S. Application Data
(63) Continuation of application No. PCT/JP2023/008689, filed on Mar. 8, 2023.

(51) Int. Cl. H03F 1/22; H03F 1/56

(52) U.S. Cl. CPC H03F 1/223; H03F 1/56

(57) ABSTRACT

An amplifier includes: an input terminal; an output terminal; at least one first amplification circuit having a first amplification element; and at least one second amplification circuit having a second amplification element in which gate to source capacitance and drain to source capacitance per unit gate width are small relative to those of the first amplification element and in which gate to drain capacitance per unit gate width is large relative to that of the first amplification element, in an operation region where a backoff amount from a saturation output power point is less than or equal to 6 dB, in which the first amplification circuit and the second amplification circuit are cascade-connected in two or more stages between the input terminal and the output terminal, and an amplification circuit connected to the output terminal is one of the first amplification circuit and the second amplification circuit.

### CROSS REFERENCE TO RELATED APPLICATION

This application is a Continuation of PCT International Application No. PCT/JP2023/008689, filed on Mar. 8, 2023, which is hereby expressly incorporated by reference into the present application.

### TECHNICAL FIELD

The present disclosure relates to an amplifier that has low distortion characteristics.

### BACKGROUND ART

Conventionally, amplifiers having low distortion characteristics are needed as, for example, amplifiers for wireless communications.

On the other hand, for example, an amplifier in which multiple amplification circuits are connected in series, and which exhibits amplitude and phase variation characteristics that are mutually opposite with respect to the input level within a predetermined input level range by means of a mechanism for detecting distortion is known (for example, refer to Patent Literature 1). This amplifier makes it possible to implement low distortion characteristics.

### CITATION LIST

### Patent Literature

Patent Literature 1: JP 2000-183663 A

### SUMMARY OF INVENTION

### Technical Problem

However, although the conventional amplifier achieves low distortion only during predetermined input power, the conventional amplifier cannot achieve low distortion during a high output operation. Here, a high output operation refers to a state in which the conventional amplifier operates in an operation region where the backoff amount from the saturation output power point is equal to or less than 6 dB.

Further, the conventional amplifier needs a mechanism for detecting distortion and a mechanism for adjusting the amplitude and phase with respect to the input level, and the circuit size of the amplifier is large.

The present disclosure is made in order to solve the above-mentioned problems, and it is therefore an object of the present disclosure to provide an amplifier that makes it possible to implement low distortion characteristics when operating in an operation region where the backoff amount from the saturation output power point is equal to or less than 6 dB.

### Solution to Problem

An amplifier according to the present disclosure includes: an input terminal; an output terminal; at least one first amplification circuit having a first amplification element; and at least one second amplification circuit having a second amplification element in which gate to source capacitance and drain to source capacitance per unit gate width are small relative to those of the first amplification element and in which gate to drain capacitance per unit gate width is large relative to that of the first amplification element, in an operation region where a backoff amount from a saturation output power point is less than or equal to 6 dB, and the first amplification circuit and the second amplification circuit are cascade-connected in two or more stages between the input terminal and the output terminal, and an amplification circuit connected to the output terminal is one of the first amplification circuit and the second amplification circuit, and an amplification circuit connected to the amplification circuit connected to the output terminal is the other one of the first amplification circuit and the second amplification circuit, and the amplification circuit connected to the output terminal is the second amplification circuit, and the amplification circuit connected to the amplification circuit connected to the output terminal is the first amplification circuit.

### Advantageous Effects of Invention

According to the present disclosure, because the amplifier is configured as above, the amplifier makes it possible to implement low distortion characteristics when operating in an operation region where the backoff amount from the saturation output power point is equal to or less than 6 dB.

### BRIEF DESCRIPTION OF DRAWINGS

FIG. 1 is a diagram showing an example of the configuration of an amplifier according to Embodiment 1;

FIG. 2A is a view showing an example of the structure of a transistor which is a first amplification element in the amplifier according to Embodiment 1, and FIG. 2B is an equivalent circuit diagram of the transistor shown in FIG. 2A;

FIG. 3A is a view showing an example of the structure of a transistor which is a second amplification element in the amplifier according to Embodiment 1, and FIG. 3B is an equivalent circuit diagram of the transistor shown in FIG. 3A;

FIG. 4 is a view showing an example of the phase characteristics with respect to the output power of a signal passing through the first amplification element in the amplifier according to Embodiment 1;

FIG. 5 is a view showing an example of the phase characteristics with respect to the output power of a signal passing through the second amplification element in the amplifier according to Embodiment 1;

FIG. 6 is a view showing an example of the phase characteristics with respect to the output power of a signal passing through the first amplification element and the second amplification element in the amplifier according to Embodiment 1;

FIG. 7 is a view showing an example of a third-order intermodulation distortion (IM3) of the amplifier according to Embodiment 1;

FIG. 8 is a diagram showing an example of the configuration of an amplifier according to Embodiment 2; and

FIG. 9 is a diagram showing an example of the configuration of an amplifier according to Embodiment 3.

### DESCRIPTION OF EMBODIMENTS

Hereinafter, the embodiments of the present disclosure will be explained in detail while referring to the drawings.

### Embodiment 1

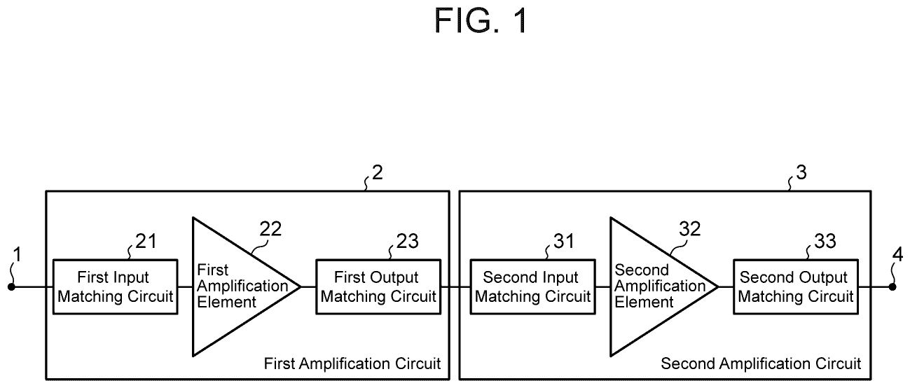

FIG. 1 is a diagram showing a configuration example showing an amplifier according to Embodiment 1.

The amplifier includes an input terminal 1, a first amplification circuit 2, a second amplification circuit 3, and an output terminal 4, as shown in FIG. 1. The first amplification circuit 2 has a first input matching circuit 21, a first amplification element 22, and a first output matching circuit 23. Further, the second amplification circuit 3 has a second input matching circuit 31, a second amplification element 32, and a second output matching circuit 33.

As this amplifier, for example, a monolithic microwave integrated circuit (MMIC) type amplifier which is configured on the same semiconductor substrate can be used.

The input terminal 1 is the one to which a high frequency signal is applied, as a signal to be amplified, from outside the amplifier. A not-illustrated load is present in this input terminal 1.

The first amplification circuit 2 amplifies a high frequency signal inputted thereto.

In the amplifier according to Embodiment 1, the first amplification circuit 2 has an input end which is connected to the input terminal 1. This first amplification circuit 2 amplifies the high frequency signal applied to the input terminal 1.

The first input matching circuit 21 matches the impedance of an input side to that of an output side.

In the amplifier according to Embodiment 1, the first input matching circuit 21 has an input end which is connected to the input terminal 1. This first input matching circuit 21 matches the load impedance of the input terminal 1 to the input impedance of the first amplification element 22.

The first amplification element 22 has an input end which is connected to an output end of the first input matching circuit 21. This first amplification element 22 amplifies the high frequency signal which has passed through the first input matching circuit 21, and amplifies the high frequency signal which is biased into class A-class B. This first amplification element 22 includes a transistor such as a field effect transistor (FET).

The first output matching circuit 23 matches the impedance of an input side to that of an output side.

In the amplifier according to Embodiment 1, the first output matching circuit 23 has an input end which is connected to an output end of the first amplification element 22, and an output end which is connected to the second input matching circuit 31. This first output matching circuit 23 matches the output impedance of the first amplification element 22 to the input impedance of the second input matching circuit 31.

The second amplification circuit 3 amplifies the high frequency signal inputted thereto.

In the amplifier according to Embodiment 1, the second amplification circuit 3 has an input end which is connected to an output end of the first amplification circuit 2, and an output end which is connected to the output terminal 4. This second amplification circuit 3 amplifies the high frequency signal amplified by the second amplification circuit 3.

The second input matching circuit 31 matches the impedance of an input side to that of an output side.

In the amplifier according to Embodiment 1, the second input matching circuit 31 has an input end which is connected to the first output matching circuit 23. This second input matching circuit 31 matches the output impedance of the first output matching circuit 23 to the input impedance of the second amplification element 32.

The second amplification element 32 has an input end which is connected to an output end of the second input matching circuit 31. This second amplification element 32 amplifies the high frequency signal which has passed through the second input matching circuit 31, and amplifies the high frequency signal which is biased into class A-class B. This second amplification element 32 includes a transistor such as an FET.

The second output matching circuit 33 matches the impedance of an input side to that of an output side.

In the amplifier according to Embodiment 1, the second output matching circuit 33 has an input end which is connected to an output end of the second amplification element 32, and an output end which is connected to the output terminal 4. This second output matching circuit 33 matches the output impedance of the second amplification element 32 to the load impedance of the output terminal 4.

In the amplifier according to Embodiment 1, the output terminal 4 is connected to the output end of the second output matching circuit 33. A not-illustrated load is present in this output terminal 4.

Further, the first amplification element 22 is a transistor in which gate to source capacitance (Cgs) and drain to source capacitance (Cds) per unit gate width are large relative to those of the second amplification element 32, and in which gate to drain capacitance (Cgd) is small relative to that of the second amplification element 32, in an operation region where a backoff amount from a saturation output power point is less than or equal to 6 dB.

In other words, the second amplification element 32 is a transistor in which Cgs and Cds per unit gate width are small relative to those of the first amplification element 22, and in which Cgd per unit gate width is large relative to that of the first amplification element 22, in the operation region where the backoff amount from the saturation output power point is less than or equal to 6 dB.

In the amplifier according to Embodiment 1 shown in FIG. 1, the amplification circuit connected to the output terminal 4 is the second amplification circuit 3, and the amplification circuit connected to the second amplification circuit 3 is the first amplification circuit 2.

Next, an example of the structure of the first amplification element 22 will be explained.

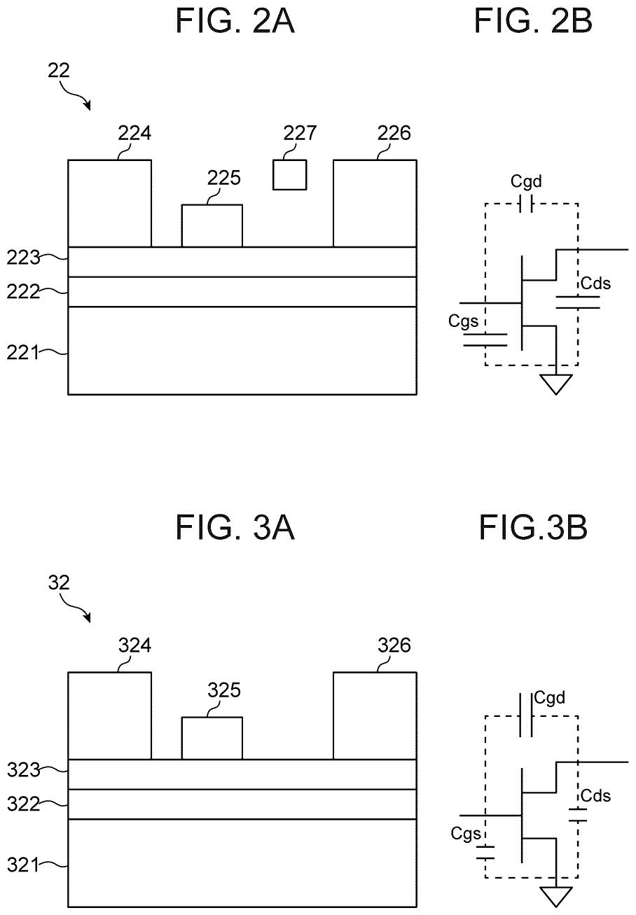

FIG. 2A is a view showing an example of the structure of the transistor which is the first amplification element 22 in the amplifier according to Embodiment 1, and FIG. 2B is an equivalent circuit diagram of the transistor shown in FIG. 2A.

The transistor which is the first amplification element 22 has a substrate 221, a GaN layer 222, an AlGaN layer 223, a source electrode 224, a gate electrode 225, a drain electrode 226, and a small source electrode 227, for example, as shown in FIG. 2.

The substrate 221 is one which is used for a semiconductor such as Si, SiC, GaN, or diamond.

The GaN layer 222 is a semiconductor layer which is formed on an upper surface of the substrate 221.

The AlGaN layer 223 is a semiconductor layer which is formed on an upper surface of the GaN layer 222.

Another semiconductor layer may be added to the GaN layer 222 and the AlGaN layer 223 as long as the same advantageous effect as that provided by an FET is provided.

Further, the source electrode 224, the gate electrode 225, and the drain electrode 226 are electrodes which are formed on an upper surface of the AlGaN layer 223, and which form the transistor.

The small source electrode 227 is formed between the gate electrode 225 and the drain electrode 226, and has the same electric potential as the source electrode 224.

As this small source electrode 227, an electrode having either a source field plate structure for improving the high frequency characteristics of the transistor, or the same advantageous effect as that provided by the source field plate structure can be used.

An equivalently coupling capacitance (Cgs) then occurs between that small source electrode 227 and the gate electrode 225, as shown in FIG. 2B. Further, an equivalently coupling capacitance (Cds) occurs between the small source electrode 227 and the drain electrode 226. Further, an equivalently coupling capacitance (Cgd) occurs also between the gate electrode 225 and the drain electrode 226, but the degree of coupling of this Cgd is suppressed by the small source electrode 227.

Therefore, the first amplification element 22 is the transistor in which Cgs and Cds per unit gate width are relatively large, and in which Cgd per unit gate width is relatively small, because of the presence of the small source electrode 227.

Next, an example of the structure of the second amplification element 32 will be explained.

FIG. 3A is the view showing an example of the structure of the transistor which is the second amplification element 32 in the amplifier according to Embodiment 1, and FIG. 3B is an equivalent circuit diagram of the transistor shown in FIG. 3A.

The transistor which is the second amplification element 32 has a substrate 321, a GaN layer 322, an AlGaN layer 323, a source electrode 324, a gate electrode 325, and a drain electrode 326, for example, as shown in FIG. 3.

The substrate 321 is one which is used for a semiconductor such as Si, SiC, GaN, or diamond.

The GaN layer 322 is a semiconductor layer which is formed on an upper surface of the substrate 321.

The AlGaN layer 323 is a semiconductor layer which is formed on an upper surface of the GaN layer 322.

Another semiconductor layer may be added to the GaN layer 322 and the AlGaN layer 323 as long as the same advantageous effect as that provided by an FET is provided.

Further, the source electrode 324, the gate electrode 325, and the drain electrode 326 are electrodes which are formed on an upper surface of the AlGaN layer 323, and which form the transistor.

More specifically, the transistor which is the second amplification element 32 shown in FIG. 3 has a transistor structure without the small source electrode 227 as compared to the transistor which is the first amplification element 22 shown in FIG. 2.

In this case, the second amplification element 32 is the transistor in which the number of couplings of the electrodes is small and Cgs and Cds are small as compared to those of the first amplification element 22, because of the absence of the small source electrode 227.

Further, the second amplification element 32 is the transistor in which Cgd is large as compared to that of the first amplification element 22 because of the absence of the small source electrode 227 between the gate electrode 325 and the drain electrode 326, which interferes with the coupling therebetween.

Therefore, the second amplification element 32 is the transistor in which Cgs and Cds per unit gate width are small relative to those of the first amplification element 22, and in which Cgd per unit gate width is large relative to that of the first amplification element 22, because of the absence of the small source electrode 227.

Next, the advantageous effect of the amplifier according to Embodiment 1 shown in FIG. 1 will be explained.

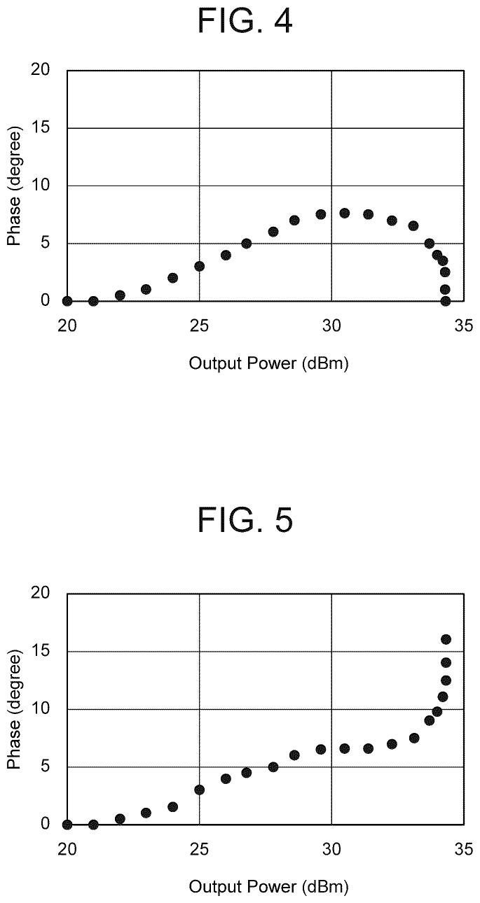

FIG. 4 is a view showing an example of the phase characteristics with respect to the output power of a signal passing through the first amplification element 22 in the amplifier according to Embodiment 1. In this FIG. 4, the horizontal axis shows the output power [dBm] of the signal passing through the first amplification element 22, and the vertical axis shows the phase [degree] of that signal.

As shown in this FIG. 4, because the amplitudes of the gate and drain voltages in the first amplification element 22 become large and the influence of the values of Cgs, Cds, and Cgd becomes large when the input power to the first amplification element 22 becomes large, the phase changes. Because the influence of the electron trap caused by Cgd during a high output operation is small and the electron trap caused by Cgs and Cds during the high output operation is large in the first amplification element 22, the phase changes greatly in a negative direction.

FIG. 5 is a view showing an example of the phase characteristics with respect to the output power of a signal passing through the second amplification element 32 in the amplifier according to Embodiment 1. In this FIG. 5, the horizontal axis shows the output power [dBm] of the signal passing through the second amplification element 32, and the vertical axis shows the phase [degree] of that signal.

As shown in this FIG. 5, because the amplitudes of the gate and drain voltages in the second amplification element 32 become large and the influence of the values of Cgs, Cds, and Cgd becomes large when the input power to the second amplification element 32 becomes large, the phase changes. Because the influence of the electron trap caused by Cgd during a high output operation is large and the electron trap caused by Cgs and Cds during the high output operation is small in the second amplification element 32, the phase changes greatly in a positive direction.

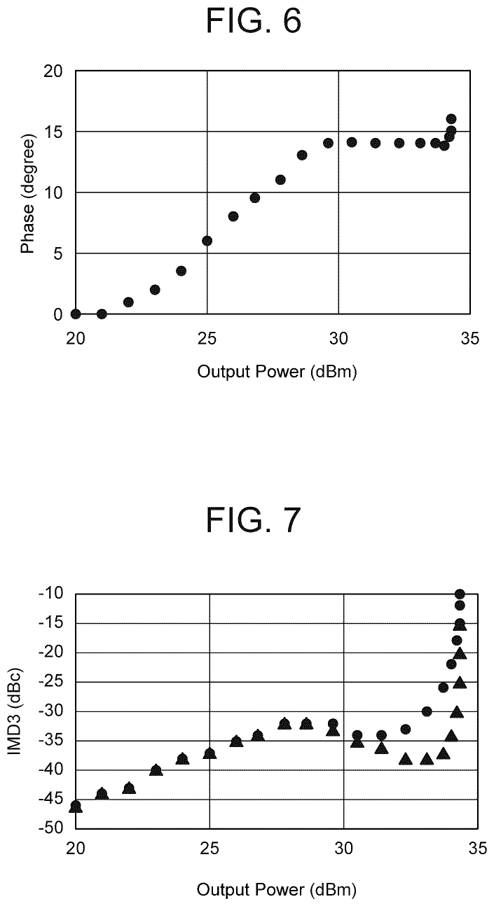

FIG. 6 is a view showing an example of the phase characteristics with respect to the output power of a signal passing through the first amplification element 22 and the second amplification element 32 in the amplifier according to Embodiment 1. In this FIG. 6, the horizontal axis shows the output power [dBm] of the signal passing through the first amplification element 22 and the second amplification element 32, and the vertical axis shows the phase [degree] of that signal.

As shown in this FIG. 6, the phase characteristics of the first amplification element 22 and those of the second amplification element 32 are combined for the signal passing through the first amplification element 22 and the second amplification element 32, and therefore the amount of change in the phase becomes small during the high output operation.

FIG. 7 is a view showing an example of a third-order intermodulation distortion (IM3) of the amplifier according to Embodiment 1. In this FIG. 7, the horizontal axis shows the output power [dBm] of the amplifier, and the vertical axis shows IM3 [dBc]. Further, in FIG. 7, black circles show the case of a conventional amplifier and black triangles show the case of the amplifier according to Embodiment 1.

As shown in this FIG. 7, it can be understood that in the amplifier according to Embodiment 1, the IM3 characteristics are improved during the high output operation, compared to those of the conventional amplifier, and low-distortion characteristics can be achieved without any external control mechanism.

As mentioned above, according to this Embodiment 1, the amplifier includes: the input terminal 1; the output terminal 4; at least one first amplification circuit 2 having the first amplification element 22; and at least one second amplification circuit 3 having the second amplification element 32 in which the gate to source capacitance and the drain to source capacitance per unit gate width are small relative to those of the first amplification element 22 and in which the gate to drain capacitance per unit gate width is large relative to that of the first amplification element, in the operation region where the backoff amount from the saturation output power point is less than or equal to 6 dB, and the first amplification circuit 2 and the second amplification circuit 3 are cascade-connected in two or more stages between the input terminal 1 and the output terminal 4, and an amplification circuit connected to the output terminal 4 is one of the first amplification circuit 2 and the second amplification circuit 3, and an amplification circuit connected to the amplification circuit connected to the output terminal 4 is the other one of the first amplification circuit 2 and the second amplification circuit 3. As a result, the amplifier according to Embodiment 1 makes it possible to implement low distortion characteristics when operating in the operation region where the backoff amount from the saturation output power point is less than or equal to 6 dB.

Further, the amplifier according to Embodiment 1 does not require a mechanism for detecting distortion and a mechanism for adjusting the amplitude and phase with respect to the input level, which are like those of conventional amplifiers. Therefore, in the amplifier according to Embodiment 1, the increase in circuit size can be suppressed and hence a reduction in size can be achieved, compared to conventional amplifiers.

### Embodiment 2

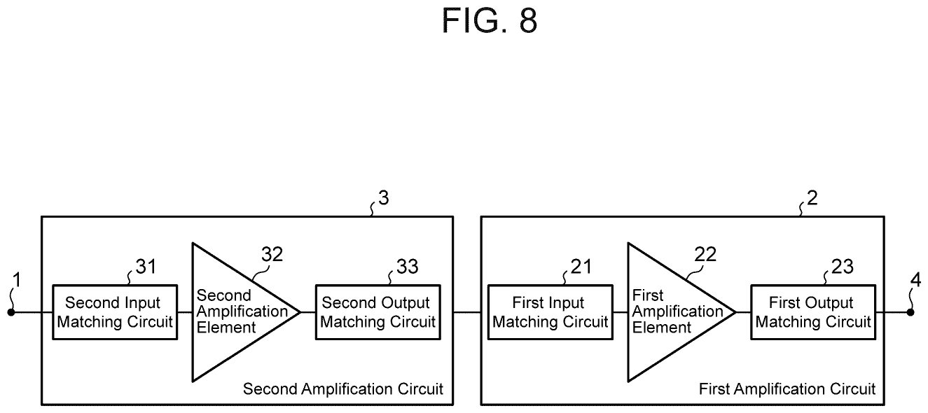

The case in which in the amplifier according to the Embodiment 1 shown in FIG. 1, the amplification circuit connected to the output terminal 4 is the second amplification circuit 3 and the amplification circuit connected to that amplification circuit connected to the second amplification circuit 3 is the first amplification circuit 2 is shown above. However, it is not limited to this example, and an amplification circuit connected to an output terminal 4 may be a first amplification circuit 2, and an amplification circuit connected to the first amplification circuit 2 may be a second amplification circuit 3, for example, as shown in FIG. 8.

FIG. 8 is a diagram showing an example of the configuration of an amplifier according to Embodiment 2.

In the amplifier according to Embodiment 2 shown in this FIG. 8, the connection order of the first amplification circuit 2 and the second amplification circuit 3 is reversed from that in the amplifier according to the Embodiment 1 shown in FIG. 1. More specifically, in the amplifier according to Embodiment 2, the second amplification circuit 3 has an input end which is connected to an input terminal 1, and the first amplification circuit 2 has an input end which is connected to an output end of the second amplification circuit 3, and an output end which is connected to the output terminal 4.

The amplifier according to Embodiment 2 shown in FIG. 8 is the same as the amplifier according to Embodiment 1 shown in FIG. 1, with the exception that the connection order is reversed, and the transistor structures of the first amplification element 22 and the second amplification element 32 are the same as those of the amplifier according to Embodiment 1.

The amplifier according to Embodiment 2 shown in this FIG. 8 also provides the same advantageous effect as that provided by the amplifier according to Embodiment 1 shown in FIG. 1.

As mentioned above, the amplification circuit connected to the output terminal 4 may be any of the first amplification circuit 2 and the second amplification circuit 3. Note that, the amplification circuit connected to the output terminal 4 and the amplification circuit connected as a stage preceding that amplification circuit need to have a relationship in which an amplification circuit having an amplification element in which Cgs and Cds are relatively large and in which Cgd is relatively small and an amplification circuit having an amplification element in which Cgs and Cds are relatively small and in which Cgd is relatively large are connected alternately.

### Embodiment 3

The case in which the two stages including a first amplification circuit 2 and a second amplification circuits 3 are cascade-connected both in the amplifier according to Embodiment 1 shown in FIG. 1 and in the amplifier according to Embodiment 2 shown in FIG. 8 are shown above. However, it is not limited to this example, and three or more stages including one or more first amplification circuits 2 and one or more second amplification circuits 3 may be cascade-connected.

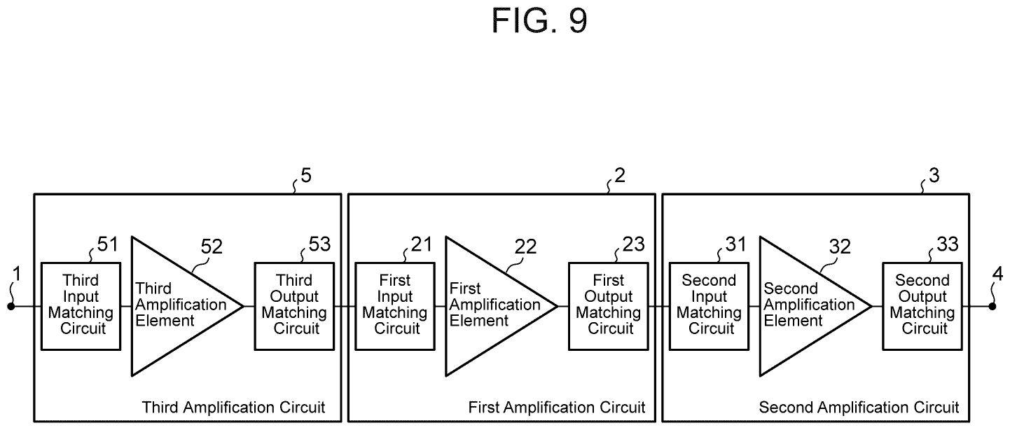

FIG. 9 is a diagram showing an example of the configuration of an amplifier according to Embodiment 3.

In the amplifier according to Embodiment 3 shown in this FIG. 9, a third amplification circuit 5 is added to the amplifier according to Embodiment 1 shown in FIG. 1. The third amplification circuit 5 has a third input matching circuit 51, a third amplification element 52, and a third output matching circuit 53. This third amplification circuit 5 is the same as either a first amplification circuit 2 or a second amplification circuit 3. An example of the other components of the amplifier according to Embodiment 3 shown in this FIG. 9 is the same as that of the amplifier according to Embodiment 1 shown in FIG. 1, and those components are denoted by the same reference signs and an explanation of the components will be omitted hereinafter.

The third amplification circuit 5 amplifies a high frequency signal inputted thereto.

In the amplifier according to Embodiment 3, the third amplification circuit 5 has an input end which is connected to an input terminal 1. This third amplification circuit 5 amplifies the high frequency signal applied to the input terminal 1.

The third input matching circuit 51 matches the impedance of an input side to that of an output side.

In the amplifier according to Embodiment 3, the third input matching circuit 51 has an input end which is connected to the input terminal 1. This third input matching circuit 51 matches the load impedance of the input terminal 1 to the input impedance of the third amplification element 52.

The third amplification element 52 has an input end which is connected to an output end of the third input matching circuit 51. This third amplification element 52 amplifies the high frequency signal which has passed through the third input matching circuit 51, and amplifies the high frequency signal which is biased into class A-class B. This third amplification element 52 is the same as a first amplification element 22 or a second amplification element 32.

The third output matching circuit 53 matches the impedance of an input side to that of an output side.

In the amplifier according to Embodiment 3, the third output matching circuit 53 has an input end which is connected to an output end of the third amplification element 52, and an output end which is connected to a first input matching circuit 21. This third output matching circuit 53 matches the output impedance of the third amplification element 52 to the input impedance of the first input matching circuit 21.

In the amplifier according to Embodiment 3, the first amplification circuit 2 has an input end which is connected to an output end of the third amplification circuit 5. This first amplification circuit 2 amplifies the high frequency signal amplified by the third amplification circuit 5.

The amplifier according to Embodiment 3 shown in this FIG. 9 also provides the same advantageous effect as that provided by the amplifier according to Embodiment 1 shown in FIG. 1.

In the amplifier according to Embodiment 3 shown in FIG. 9, the configuration in which the third amplification circuit 5 is cascade-connected in a stage preceding the first amplification circuit 2 in the amplifier according to Embodiment 1 shown in FIG. 1 is shown.

However, it is not limited to this example, and a configuration in which the third amplification circuit 5 is cascade-connected in a stage preceding the second amplification circuit 3 in the amplifier according to Embodiment 2 shown in FIG. 8 may be provided.

Further, in FIG. 9, the case in which the first amplification circuit 2, the second amplification circuit 3, and the third amplification circuit 5 are cascade-connected is shown.

In addition to this configuration, another amplification circuit may be further cascade-connected in a stage preceding the third amplification circuit 5. The amplification circuit which is connected additionally is also the same as the first amplification circuit 2 or the second amplification circuit 3.

It is to be understood that any combination of embodiments can be made, a change can be made in any component of each of the embodiments, or any component in each of the embodiments can be omitted.

### INDUSTRIAL APPLICABILITY

The amplifier according to the present disclosure is suitable for use as amplifiers and so on which make it possible to implement low distortion characteristics when operating in the operation region where the backoff amount from the saturation output power point is less than or equal to 6 dB, and hence have low distortion characteristics.

### REFERENCE SIGNS LIST

1 input terminal, 2 first amplification circuit, 3 second amplification circuit, 4 output terminal, 5 third amplification circuit, 21 first input matching circuit, 22 first amplification element, 23 first output matching circuit, 31 second input matching circuit, 32 second amplification element, 33 second output matching circuit, 51 third input matching circuit, 52 third amplification element, 53 third output matching circuit, 221 substrate, 222 GaN layer, 223 AlGaN layer, 224 source electrode, 225 gate electrode, 226 drain electrode, 227 small source electrode, 321 substrate, 322 GaN layer, 323 AlGaN layer, 324 source electrode, 325 gate electrode, and 326 drain electrode.

1. An amplifier comprising:
an input terminal;
an output terminal;
at least one first amplification circuit having a first amplification element; and
at least one second amplification circuit having a second amplification element in which gate to source capacitance and drain to source capacitance per unit gate width are small relative to those of the first amplification element and in which gate to drain capacitance per unit gate width is large relative to that of the first amplification element, in an operation region where a backoff amount from a saturation output power point is less than or equal to 6 dB,
wherein the first amplification circuit and the second amplification circuit are cascade-connected in two or more stages between the input terminal and the output terminal, and
an amplification circuit connected to the output terminal is one of the first amplification circuit and the second amplification circuit, and an amplification circuit connected to the amplification circuit connected to the output terminal is the other one of the first amplification circuit and the second amplification circuit,
the amplification circuit connected to the output terminal is the second amplification circuit, and the amplification circuit connected to the amplification circuit connected to the output terminal is the first amplification circuit.

2. The amplifier according to claim 1, wherein the first amplification element includes:
a source electrode;
a gate electrode;
a drain electrode; and
a small source electrode which is formed between the gate electrode and the drain electrode and which has a same electric potential as that of the source electrode.

3. The amplifier according to claim 1, wherein the first amplification circuit and the second amplification circuit are configured on a same semiconductor substrate.
